(19) United States
(12) Patent Application Publication
(10) Pub. No.: US 2010/0090274 A1
(43) Pub. Date: Apr. 15, 2010

(54) TRENCH MOSFET WITH SHALLOW TRENCH CONTACT

(75) Inventor: Fu-Yuan Hsieh, Hsingchu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/249,360

(22) Filed: Oct. 10, 2008

(51) Int. Cl. H01L 29/78; H01L 21/336

(52) U.S. Cl. 257/331; 438/270; 257/E29.262; 257/E21.41

(57) ABSTRACT

A trench MOSFET element with shallow trench contact is disclosed. This shallow trench contact structure has some advantages: blocking the P+ underneath trench contact from lateral diffusion to not touch to channel region when a larger trench contact CD is applied; avoiding the trench gate contact etching through poly and gate oxide when trench gate becomes shallow; making lower cost to refill the trench contact using Al alloys with good metal step coverage as the trench contact is shallower. The disclosed trench MOSFET element further includes an n* region around the bottom of gate trenches to reduce Rds. In some embodiment, the disclosed trench MOSFET provides a terrace gate to further reduce Rg and make self-aligned source contact; In some embodiment, the disclosed trench MOSFET comprises a P* area underneath said P+ region for avalanche energy improvement with lighter dose than said P+ region.

### FIELD OF THE INVENTION

This invention relates generally to the cell configuration and fabrication process of trench MOSFET devices. More particularly, this invention relates to a novel and improved cell structure and improved process of fabricating a trench MOSFET with shallow trench contact.

### BACKGROUND

A trench MOSFET with conventional deep trench contact is disclosed in FIG. 1. This trench MOSFET of prior art further comprises: a heavily N+ doped substrate 900; an N epitaxial layer 902 with lighter concentration than said substrate 900; a plurality of narrower gate trenches 904a (not shown) and at least a wider gate trench 904′a (not shown) for gate contact are etched into said epitaxial layer 902, said narrower gate trenches 904a and at least a wider gate trench 904′a are filled with doped poly to serve as narrower trench gates 904 and at least a wider trench gate 904′ for gate contact over a gate oxide layer 914; a plurality of P-body regions 906 formed in said epitaxial layer and extending between said narrower trench gates 904 and least a wider trench gate 904′ for gate contact; source regions 908 with an opposite dopant type to P-body near the top surface of epitaxial layer 902 between said narrower trench gates 904; source-body contact trenches 910a (not shown) and at least a gate contact trench 910′a (not shown) penetrating through a layer of thick contact oxide 912, gate oxide layer 914, source regions 908 and into P-body regions 906, said source-body contact trenches 910a and at least a gate trench 910′a are filled with Ti/TiN/W to serve as trench source-body contact 910 and trench gate contact 910′, respectively; an P+ area 916 around the bottom of each said trench source-body contact to provide a low-resistance between trench source-body contact and P-body regions; source metal layer 920 which is Al Alloys onto a layer of source interconnection metal 918 which is Ti or Ti/TiN to connect source regions; gate metal layer 920′ which is Al Alloys onto a layer of gate interconnection metal 918′ which is Ti or Ti/TiN to connect gate portion.

There are some disadvantages of the prior art. First, during fabrication process, if the trench contact CD (Critical Dimension) is larger, the P+ area 916 around bottom of each said trench source-body contact 910 will easily touch to channel region, as shown in FIG. 2, which is because that, inside P-body region 906 between narrower trench gates, contact silicon depth (Dcsi, as illustrated) is deeper than n+ source depth (Dn+, as illustrated), so there is no any stopper around said trench source-body contact bottom to block the P+ lateral diffusion, which will result in higher Rds due to higher threshold voltage, therefore it makes less tolerance in trench contact CD variation.

Another disadvantage of the prior art is that, please refer to FIG. 2 again, since doped poly silicon has higher etch rate than single crystal, the gate contact trench 910′a will be deeper than source-body contact trench 910a, and may be etched through doped poly 904′ and gate oxide layer 914 when gate trenches become shallow, which will cause gate/drain shortage issue.

Another disadvantage of the prior art is that, refilling contact trenches 910a and 910′a, traditional tungsten plugs, as used in structure of FIG. 2, are not helpful to make a low-cost, thus, front metal Al Alloys is considered to be filled into contact trenches to serve as metal plug as well. However, this method will lead to a bad metal connection performance as Al Alloys can not refill easily in the deep contact trenches.

Accordingly, it would be desirable to provide a new trench MOSFET configuration solving the problems mentioned above and achieving a better working performance than prior art.

### SUMMARY OF THE INVENTION

It is therefore an object of the present invention to provide new and improved trench MOSFET element and manufacture process to prevent the P+ area touching to channel region issue and gate/drain shortage issue from happening, and to make a better connection performance while maintaining a lower cost.

One aspect of the present invention is that, a shallow trench contact structure is invented to resolve some of the problems discussed above. First, while employing this shallow trench contact structure, contact silicon depth (Dcsi) is shallower than n+ source depth (Dn+), which well avoids the P+ area touching to channel region issue due to n+ source blocking P+ area from lateral diffusion as stopper, thus, the relevant increasing of Rds can be prevented. FIG. 3 shows that when a wider contact CD is applied, P+ around the source-body contact trench bottom is inherently blocked by n+ source, which makes more contact CD tolerance. On the other hand, since the contact trench is shallower than conventional, Al alloys can refill the trench contact with good metal step coverage instead of W metal plug in some preferred embodiments, making a cost down for mass production. However, different from the traditional process, in order to implement this shallow trench contact structure, after the P-body area formation, Ion Implantation is applied first to form n+ source layer, then contact trenches are etch through thick contact oxide layer and n+ source layer, and n+ source diffusion is subsequently followed to form a given n+ source depth which is deeper than source contact trench.

Another aspect of the present invention is that, the MOSFET further includes trench floating rings as termination to avoid degradation of breakdown voltage resulted from shallow trench structure.

Another aspect of the present invention is that, the bottom of all trench gates, including floating trench gates, are wrapped with n* areas which are heavier doped than epitaxial layer to further reduce Rds.

Another aspect of the present invention is that, terrace gate structure is applied in some preferred embodiments to avoid the gate contact trench etching through gate oxide issue. Meanwhile, the terrace gate structure can further reduce Rg as terrace trench gate provides additional poly over silicon mesa area; At the same time, a self-aligned source contact is achieved by this terrace gate structure solving avalanche current and Rds non-uniform distribution issue resulted from misalignment between trench contact and trench gate.

Another aspect of the present invention is that, in some preferred embodiments, there is additional P* region underneath the P+ area around each bottom of trench source-body contact. Said P* region is Ion Implanted with dose less than P+ area but higher than P-body for avalanche energy improvement without significantly affecting threshold voltage due to lighter dose than P+ area. In fabrication process, the P* Ion Implantation energy is higher than P+ in order to form P* region underneath P+.

Briefly, in a preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those said trenches, at least a wider trench is formed for gate contact; a gate oxide layer on the front surface of epitaxial layer and along the inner surface of said gate trenches and floating gate trenches; doped poly filled within said gate trenches and floating gate trenches to form trench gates and floating trench gates; n* regions wrapping the round bottom of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention; P+ area underneath each source-body contact trench to provide a low resistance between contact metal and P-body region; metal Ti/TiN/W refilled into contact trenches acting as contact metal; metal Al alloys deposited to serve as front metal onto an interconnection layer of Ti or TiN.

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those said trenches, at least a wider trench is formed for gate contact; a gate oxide layer on the front surface of the epitaxial layer and along the inner surface of said gate trenches and floating gate trenches; doped poly filled within said gate trenches to form trench gates and floating trench gates; n* regions wrapping the round bottom of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention; P+ area underneath each source-body contact trench to provide a low resistance between contact metal and P-body region; metal Ti/TiN/Al alloys refilled the contact trenches to act as contact metal and front metal as well.

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those said trenches, at least a wider gate trench is formed for gate contact; a gate oxide layer on the surface of epitaxial layer and along the inner surface of said gate trenches and floating gate trenches; doped poly filling within floating gate trenches serving as floating trench gates; doped poly refilling other gate trenches above the trench top to form terrace trench gates; n* regions wrapping the round bottoms of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention, and what should be noticed is that, when etching the source-body contact trench, silicon contact width is smaller than the oxide contact width to form the self-aligned structure; P+ area underneath each source-body contact trench to provide a low resistance between contact metal and P-body region; metal W acting as trench contact filler; front metal Al alloys onto an interconnection metal layer of Ti or Ti/TiN.

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those said gate trenches, at least a wider gate trench is formed for gate contact; a gate oxide layer along the front surface of epitaxial layer and along the inner surface of said gate trenches and floating gate trenches; doped poly filling within floating gate trenches serving as floating trench gates; doped poly refilling other gate trenches above trench top to form terrace gates; n* regions wrapping the round bottoms of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention, and what should be noticed is that, when etching the source-body contact trench, silicon contact width is smaller than the oxide contact width to form the self-aligned structure; P+ area underneath each source-body contact trench to provide a low resistance between contact metal and P-body region; metal Al alloys filling the contact trenches as contact filler and front metal as well.

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those gate trenches, at least a wider gate trench is formed for gate contact; a gate oxide layer on the front surface of epitaxial layer and along the inner surface of said gate trenches and floating gate trenches; doped poly filled within said gate trenches and floating gate trenches to form trench gates and floating trench gates; n* regions wrapping the round bottoms of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention; P+ area around the bottom of each source-body contact trench to provide a low resistance between contact metal and P-body region; P* area underneath each said P+ area with dose less than said P+ area but higher than said P-body region; metal Ti/TiN/W refilled into contact trenches acting as contact metal; metal Al alloys deposited to serve as front metal onto an interconnection layer of Ti or TiN;

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those said gate trenches, at least a wider gate trench is formed for gate contact; a gate oxide layer on the front surface of epitaxial layer and along the inner surface of said gate trenches and trench gate trenches; doped poly filled within said gate trenches and floating gate trenches to form trench gates and floating trench gates; n* regions wrapping the round bottoms of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention; P+ area around each source-body contact trench to provide a low resistance between contact metal and P-body region; P* area underneath each said P+ area with dose less than said P+ area but higher than said P-body region; metal Al alloys filling contact trenches as contact metal and front metal as well.

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those gate trenches, at least a wider gate trench is formed for gate contact; a gate oxide layer on the front surface of epitaxial layer and along the inner surface of said gate trenches and floating gate trenches; doped poly filling within floating gate trenches serving as floating trench gates; doped poly refilling other gate trenches above trench top to form terrace gates; n* regions wrapping the round bottoms of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention, and what should be noticed is that, when etching the source-body contact trench, silicon contact width is smaller than the oxide contact width to form the self-aligned structure; P+ area around the bottom of each source-body contact trench to provide a low resistance between contact metal and P-body region; P* area underneath each said P+ area with dose less than said P+ area but higher than said P-body region; metal W acting as trench contact filler; front metal Al alloys onto a interconnection layer of Ti or Ti/TiN.

Briefly, in another preferred embodiment, the present invention disclosed a trench MOSFET comprising: an N+ doped substrate with a layer of Ti/Ni/Ag on the rear side serving as the drain metal; a lighter N doped epitaxial layer grown on said substrate; a plurality of trenches etched into said epitaxial layer as gate trenches and floating gate trenches, among those gate trench, at least a wider gate trench is formed for gate contact; a gate oxide layer on the front surface of epitaxial layer and along the inner surface of said gate trenches and floating gate trenches; doped poly filling within floating gate trenches serving as floating trench gates; doped poly refilling other gate trenches above trench top to form terrace gate; n* regions wrapping the round bottoms of all trench gates, including floating trench gates with a heavier doping concentration than said epitaxial layer; P-body regions extending between every two trench gates and floating trench gates; source regions Ion Implanted with a junction depth Dn+; a thick contact oxide layer; contact trenches penetrating through said contact oxide layer, said gate oxide layer and extending into said epitaxial layer with a trench Si contact depth Dcsi, and Dn+>Dcsi>0 in accordance with the present invention, and what should be noticed is that, when etching the source-body contact trench, silicon contact width is smaller than the oxide contact width to form the self-aligned structure; P+ area around the bottom of each source-body contact trench to provide a low resistance between contact metal and P-body region; P* area underneath each said P+ area with dose less than said P+ area but higher than said P-body region; metal Al alloys filling contact trenches as contact metal and front metal as well.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a trench MOSFET element of prior art.

FIG. 2 is a side cross-sectional view of a trench MOSFET element of prior art when a wider contact CD is applied.

FIG. 3 is cross-section of a trench MOSFET element with shallow trench of this invention when a wider contact CD is applied.

FIG. 4 is a cross-section of a power MOS element of an embodiment for the present invention.

FIG. 5 is a cross-section of a power MOS element of another embodiment for the present invention.

FIG. 6 is a cross-section of a power MOS element of another embodiment for the present invention.

FIG. 7 is a cross-section of a power MOS element of another embodiment for the present invention.

FIG. 8 is a cross-section of a power MOS element of another embodiment for the present invention.

FIG. 9 is a cross-section of a power MOS element of another embodiment for the present invention.

FIG. 10 is a cross-section of a power MOS element of another embodiment for the present invention.

FIG. 11 is a cross-section of a power MOS element of another embodiment for the present invention.

FIG. 12A to FIG. 12E are a serial of side cross sectional views for showing the processing steps for fabricating a power MOS element as shown in FIG. 8 (FIG. 9).

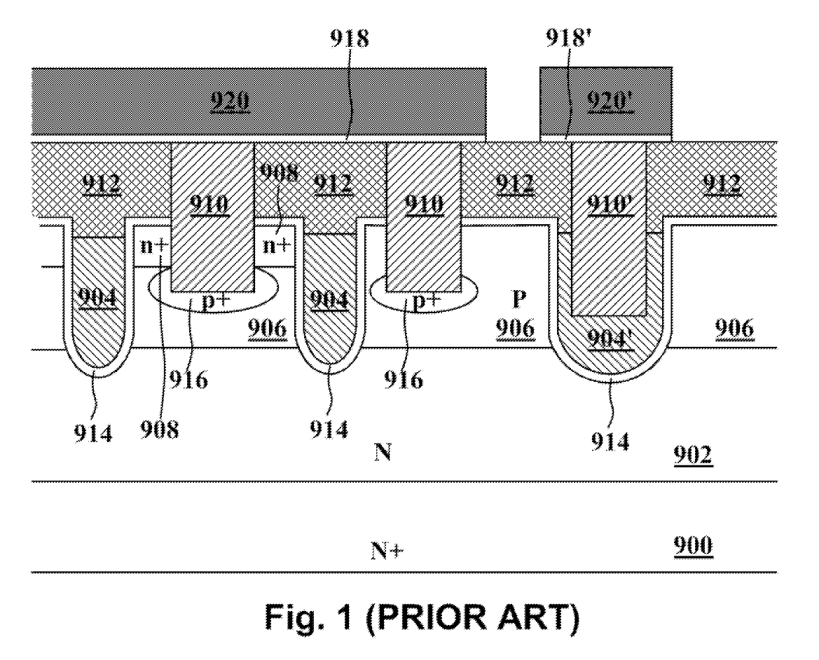

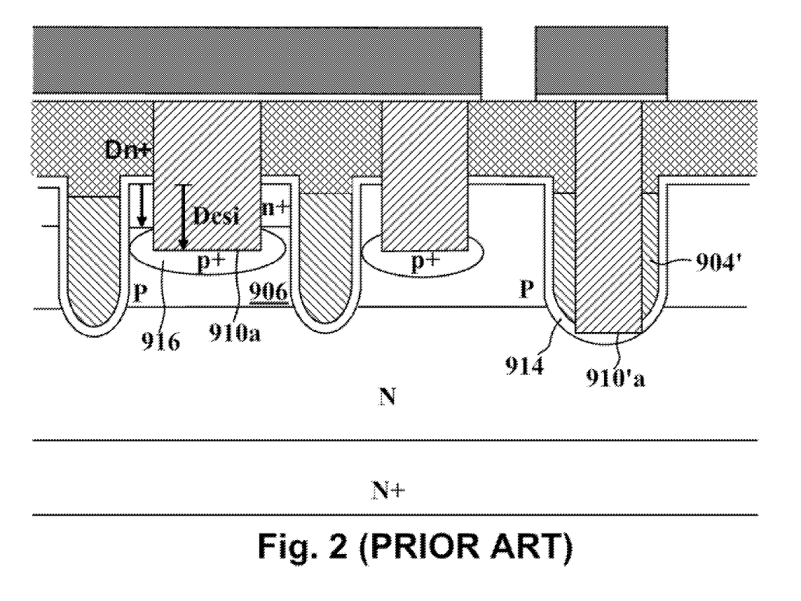

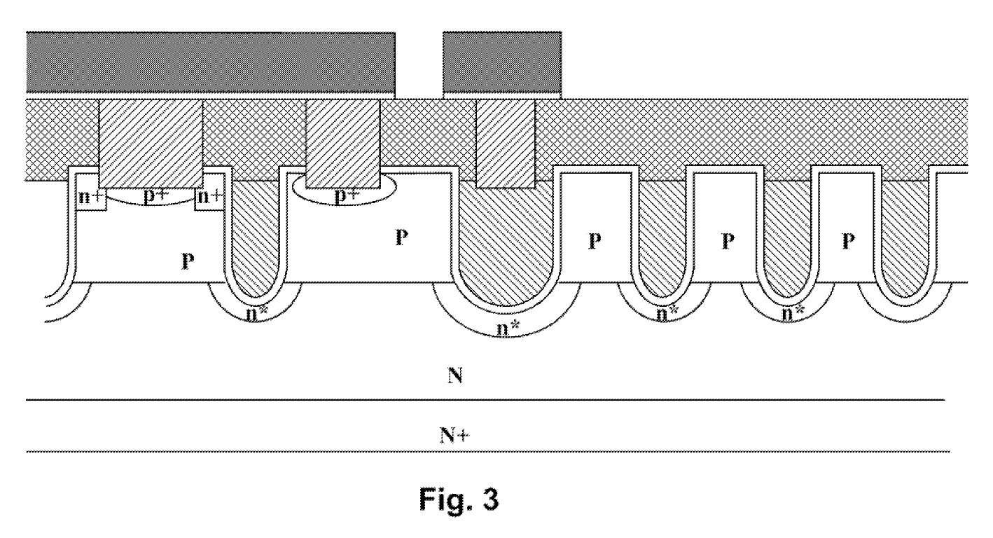

### DETAILED DESCRIPTION OF THE EMBODIMENTS

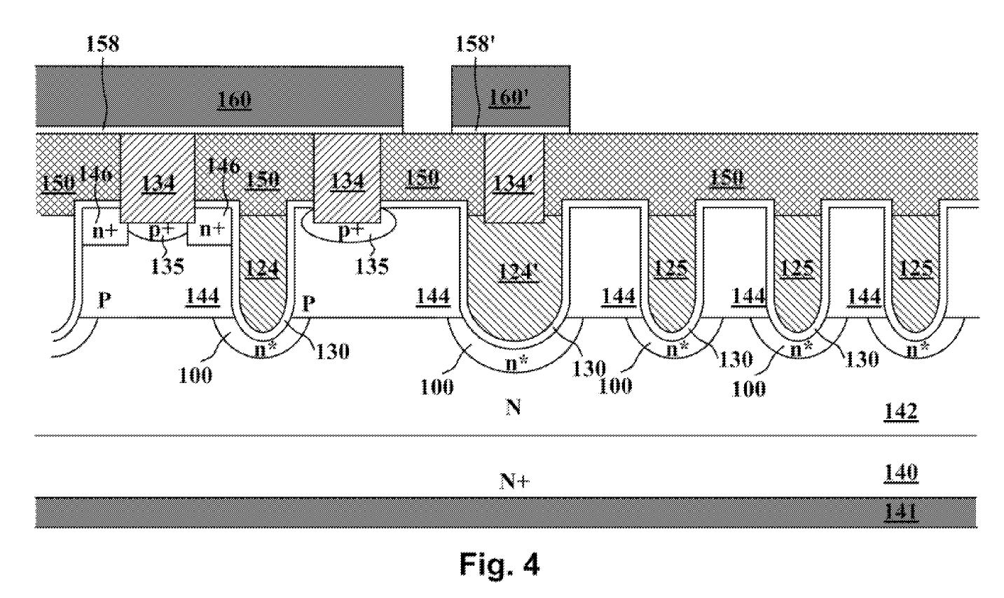

Please refer to FIG. 4 for a first preferred embodiment of this invention where a trench MOSFET element is formed on an N+ substrate 140 coated with back metal Ti/Ni/Ag 141 on rear side as drain, onto which grown an N epitaxial layer 142. The trench MOSFET element further includes gate trenches 124a (not shown), 124′a (not shown) and 125a (not shown), wherein gate trenches 125a are used as floating gate trenches and 124′a is wider than all other trenches for gate contact, all trenches are filled with doped poly onto a layer of gate oxide 130 to serve as trench gates 124, trench gate 124′ for gate contact and floating trench gates 125 as termination rings. Body regions 144 of a second conductivity type extend between all trench gates 124, 124′ and 125. It should be noticed that, around the bottom of each trench gate and floating trench gate, as shown in FIG. 4, there is an n* region 100 with a concentration heavier than epitaxial layer to further reduce Rds. Source regions 146 doped with a first doping type are formed on the top surface of the epitaxial layer between trench gates 124. Source-body contact trenches 134a are produced through contact oxide layer 150 and into said source region 146 and into said P-body region 144; gate contact trench 134′a (not shown) is produced through said contact oxide layer 150 and into said trench gate for gate contact; around the bottom of source-body contact trench, a contact P+ implantation 135 is carried out, which will help to form a low-resistance contact between trench source-body contact and the P-body region 144. To implement the shallow trench contact, the trench Si contact depth is shallower than source junction depth by process technology and therefore the P+ area 135 is blocked from lateral diffusion by N+ source 146 when a wider contact CD applied. Tungsten plugs 134 act as the source-body contact metal to connect said source region, said body region to source metal 160 via a source interconnection layer 158 of Ti or Ti/TiN; tungsten plug 134′ acts as the gate contact metal to connect said trench gate to gate metal 160′ via a gate interconnection layer 158′ of Ti or Ti/TiN.

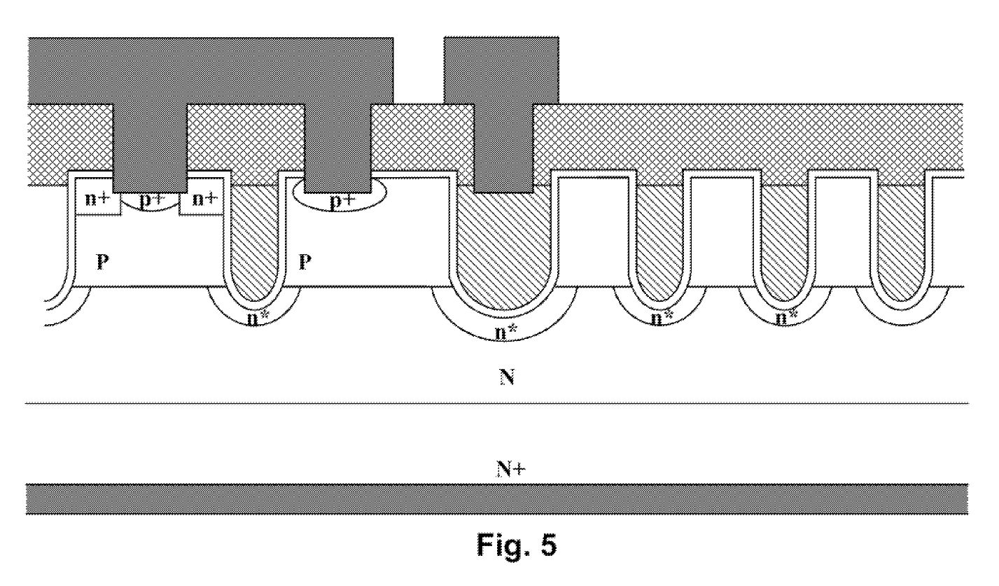

Please refer to FIG. 5 for a second preferred embodiment of this invention, wherein the trench MOSFET has the same structure with the first embodiment, except that the material used as contact trench filler and front metal are both Al alloys. That's because Al alloys can refill the shallower trench contact with good metal step coverage, thus making a lower cost than using of tungsten plug.

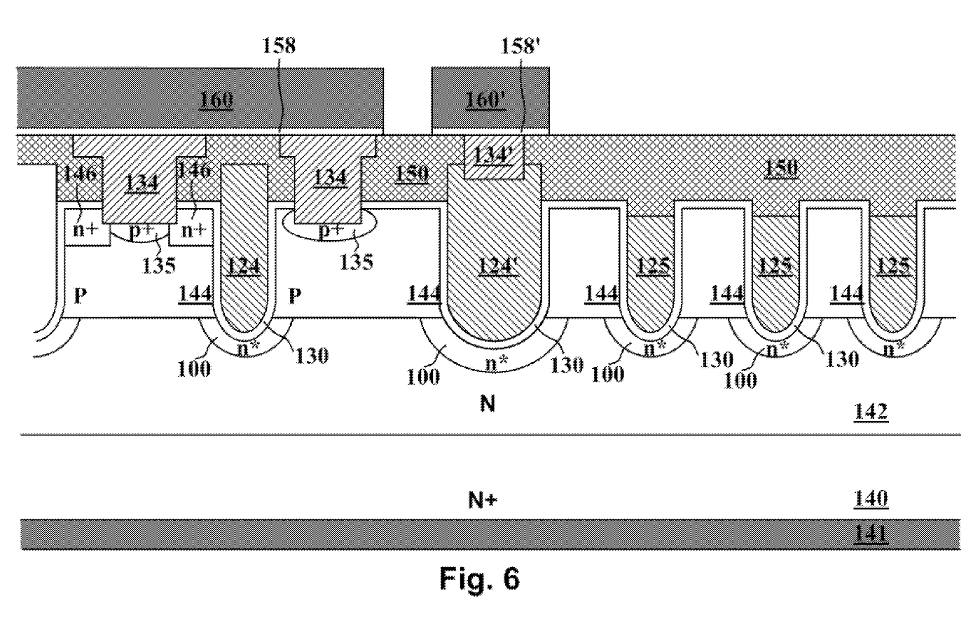

For the purpose of avoiding the trench gate contact penetrating through doped poly and gate oxide layer and resulting in shortage of metal plug to epitaxial layer when the gate trenches becomes shallower, a terrace poly gate is employed in a third preferred embodiment, as shown in FIG. 6. The trench MOSFET of this embodiment is formed on an N+ substrate 140 coated with back metal Ti/Ni/Ag 141 on rear side as drain. Onto said substrate 40, grown an N epitaxial layer 142, and a plurality of trenches 124a (not shown), 124′a (not shown) and 125a (not shown) were etched wherein, especially, gate trenches 125a are used as floating gate trenches and 124′a is wider than all other trenches for gate contact. To fill these trenches, doped poly was deposited within floating gate trenches 125a to serve as floating trench gates 125; and same doped poly was deposited in other gate trenches 124a and 124′a to form terrace gates 124 and 124′ for gate contact above trench top onto a gate oxide layer 130. Around the bottom of trench gate 124, 124′ and floating trench gate 125, there is an n* region 100 with a concentration heavier than epitaxial layer to further reduce Rds. P-body regions 144 are extending between said trench gates and floating trench gates with a layer of source region 146 near the top surface of said P-body region between trench gates 124. Onto front surface of epitaxial layer, a thick contact oxide layer 150 was deposited to form a self-aligned terrace contact structure. The key point to form terrace contact is that, when etching the contact trenches, silicon contact width is smaller than oxide contact width. Source-body contact trenches 134a (not shown) were etched through said contact oxide layer and into said n+ source region and P-body region; gate contact trench 134′a (not shown) was etched through said contact oxide layer and into said terrace gate for gate contact. At the bottom of source-body contact trench, a contact P+ implantation 135 is carried out to help to form a low-resistance contact between trench source-body contact and the P-body region 144. To implement the shallow trench contact, the trench Si contact depth is shallower than source junction depth by process technology and therefore the P+ area 135 is blocked from lateral diffusion by N+ source 146 when a wider contact CD applied. Tungsten plugs 134 act as the source contact metal to connect said source region, said body region to source metal 160 via a source interconnection layer 158 of Ti or Ti/TiN; tungsten plug 134′ acts as the gate contact metal to connect said trench gate to gate metal 160′ via a gate interconnection layer 158′ of Ti or Ti/TiN.

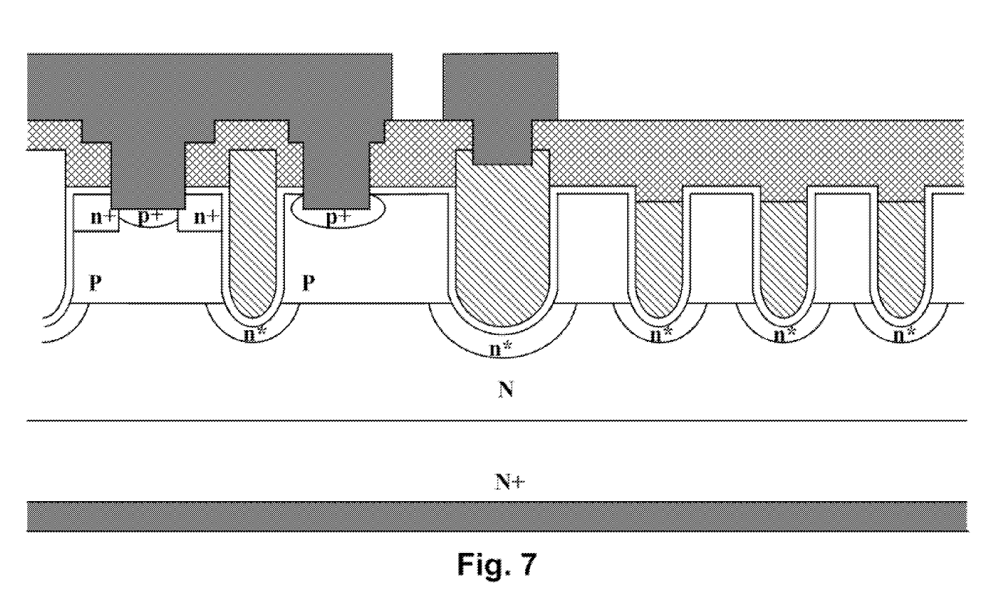

Please refer to FIG. 7 for a fourth preferred embodiment of this invention, wherein the trench MOSFET has the same structure with the third embodiment, except that the material used as trench contact filler and front metal are both Al alloys. That's because Al alloys can refill the shallower trench contact with good metal step coverage, thus making a lower cost than using of tungsten plug.

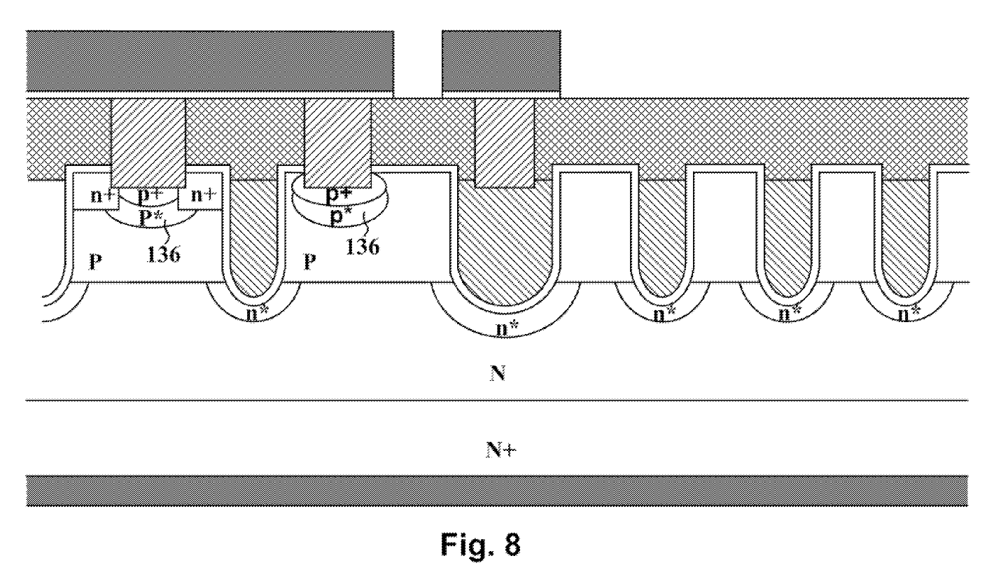

Please refer to FIG. 8 for a fifth preferred embodiment of this invention, wherein the trench MOSFET has the same structure with the first embodiment, except that there is an additional P* region 136 underneath each P+ area around the bottom of trench source-body contact. The P* region is Ion Implanted with dose less than P+ area but higher than P-body for avalanche energy improvement without significantly affecting threshold voltage due to lighter dose than P+ area. At the same time, the P* area Ion Implantation energy is higher than P+ region to form P* underneath P+.

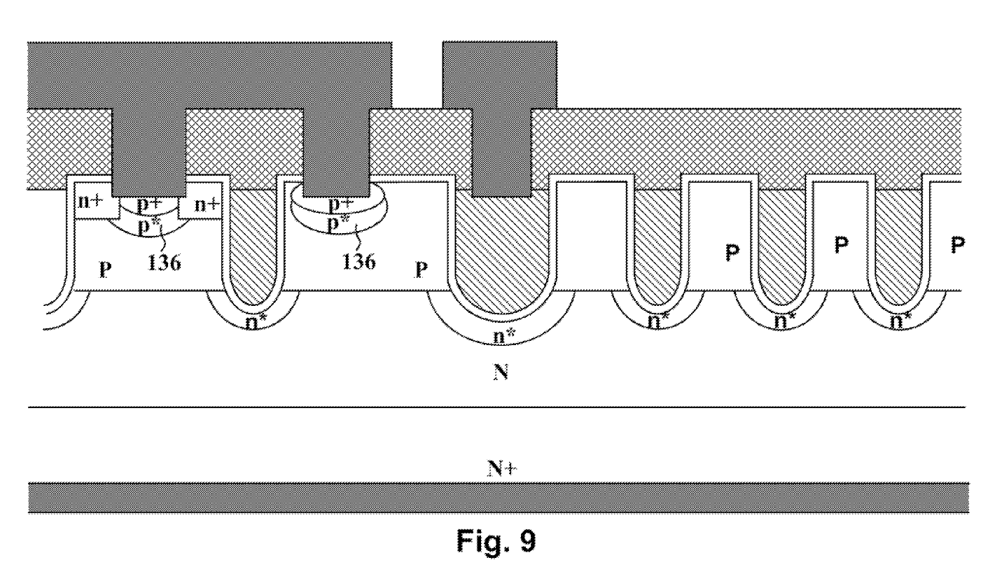

Please refer to FIG. 9 for a sixth preferred embodiment of this invention, wherein the trench MOSFET has the same structure with the second embodiment, except that there is additional P* region 136 underneath each P+ area around the bottom of trench source-body contact. The P* region is Ion Implanted with dose less than P+ area but higher than P-body for avalanche energy improvement without significantly affecting threshold voltage due to lighter dose than P+ area. At the same time, the P* area Ion Implantation energy is higher than P+ region to form P* underneath P+.

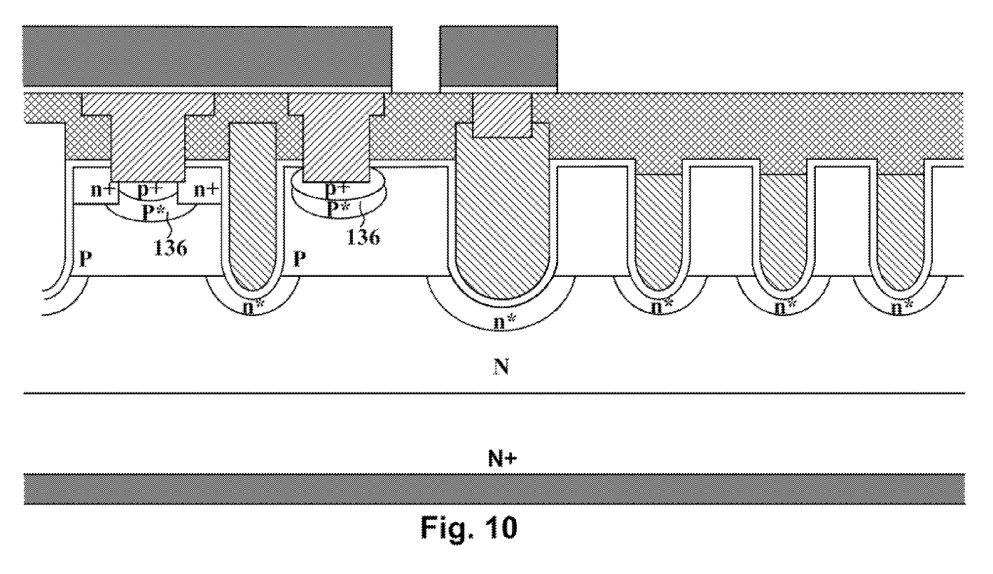

Please refer to FIG. 10 for a seventh preferred embodiment of this invention, wherein the trench MOSFET has the same structure with the third embodiment, except that there is additional P* region 136 underneath each P+ area around the bottom of trench source-body contact. The P* region is Ion Implanted with dose less than P+ area but higher than P-body for avalanche energy improvement without significantly affecting threshold voltage due to lighter dose than P+ area. At the same time, the P* area Ion Implantation energy is higher than P+ region to form P* underneath P+.

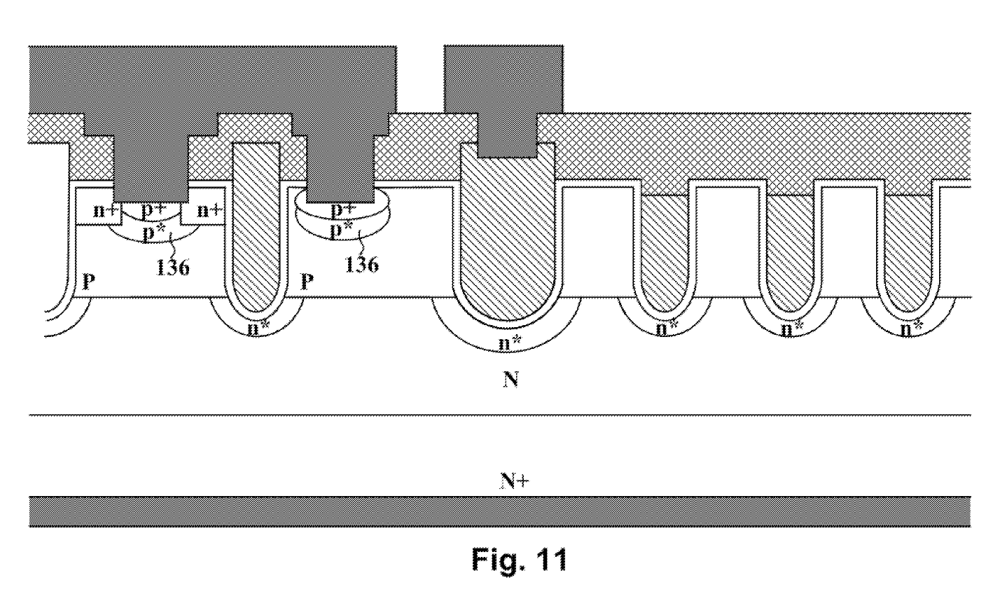

Please refer to FIG. 11 for a eighth preferred embodiment of this invention, wherein the trench MOSFET has the same structure with the fourth embodiment, except that there is additional P* region 136 underneath each P+ area around the bottom of trench source-body contact. The P* region is Ion Implanted with dose less than P+ area but higher than P-body for avalanche energy improvement without significantly affecting threshold voltage due to lighter dose than P+ area. At the same time, the P* area Ion Implantation energy is higher than P+ region to form P* underneath P+.

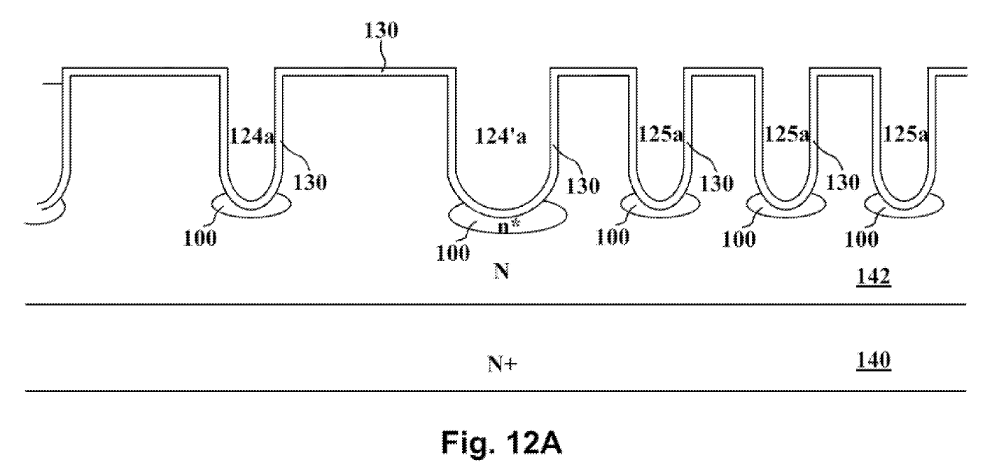

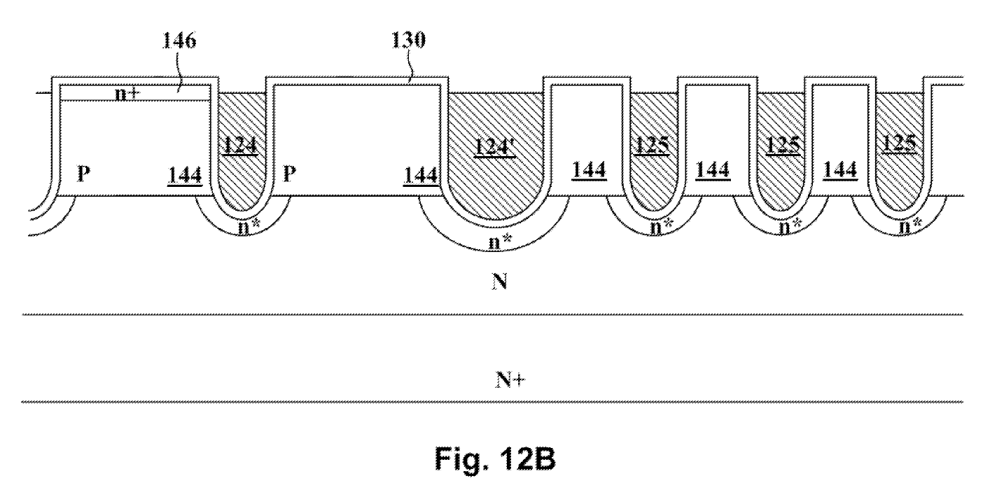

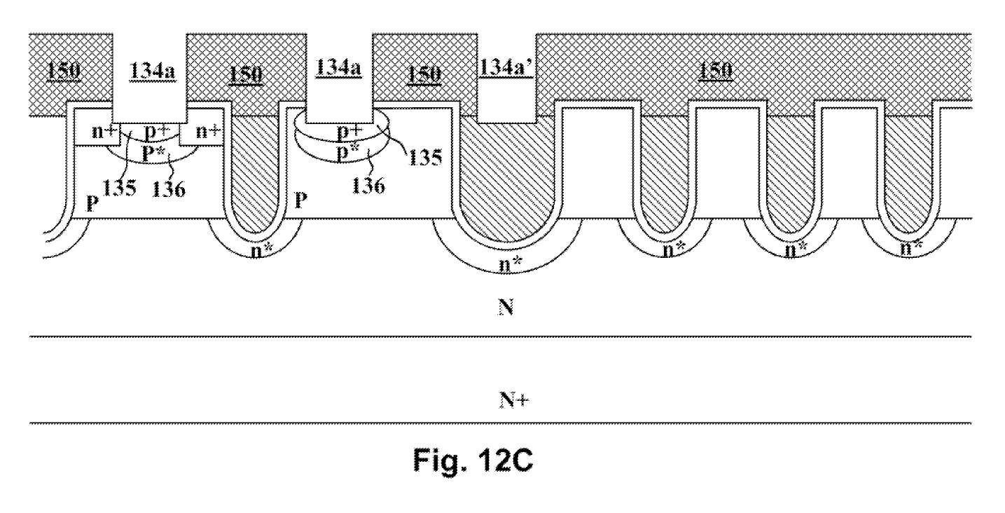

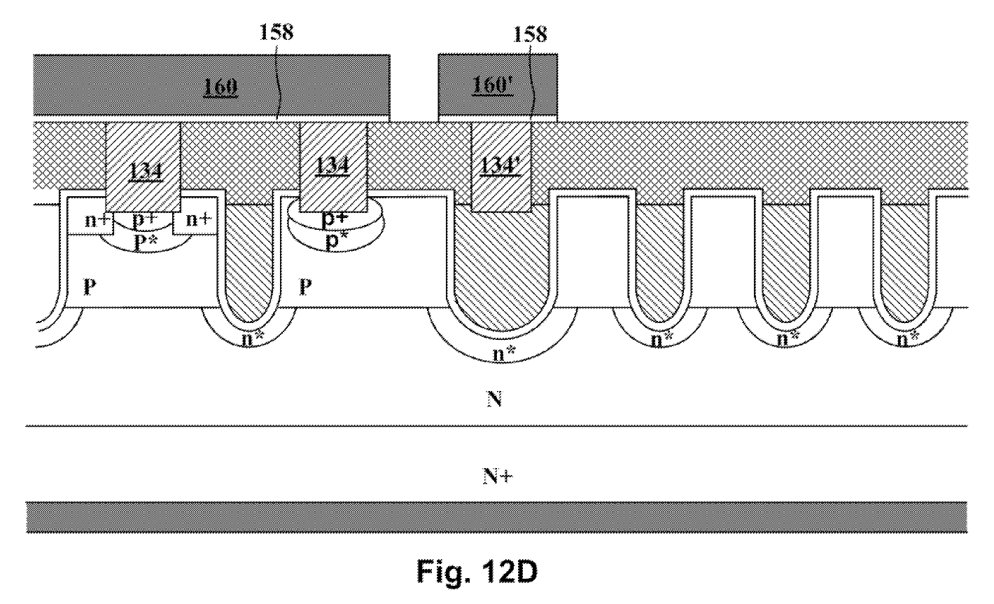

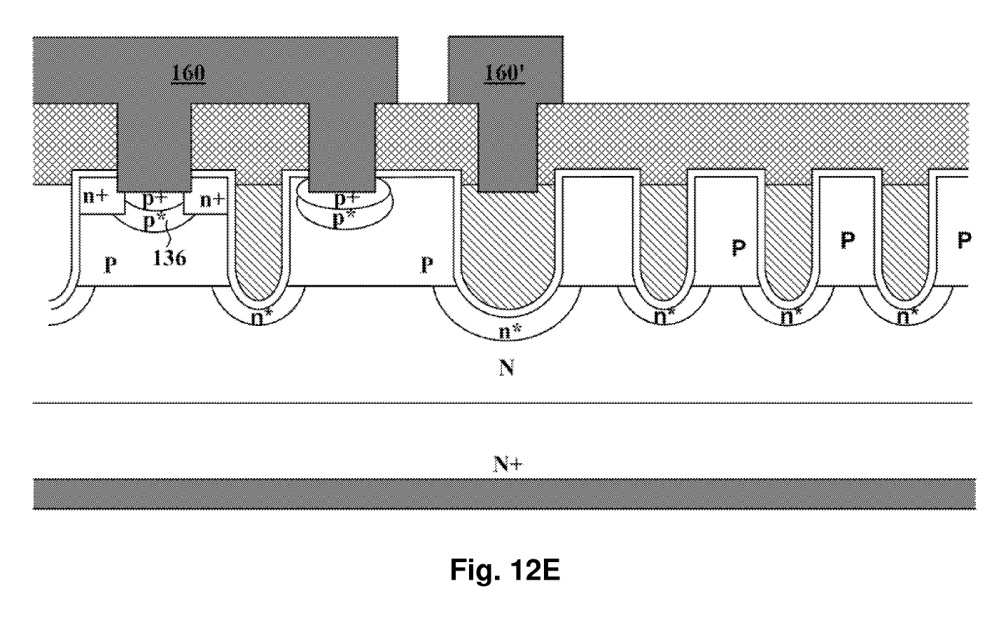

FIGS. 12A to 12E show a series of exemplary steps that are performed to form the inventive trench MOSFET element in FIG. 8 (FIG. 9). In FIG. 12A, an N-doped epitaxial layer 142 is grown on an N+ substrate 140, then, a trench mask (not shown) is applied, which is then conventionally exposed and patterned to leave mask portions. The patterned mask portions define the trenches 124a, 124′ a and floating gate trenches 125a. Trench 124a, 124′a and 125a are dry Si etched through the mask opening to a certain depth, then, the mask portion is removed. After the removal, a step of arsenic Ion Implantation is performed for n* 100 formation around each gate trench bottom for further reducing Rds. And a gate oxide layer 130 is deposited on the entire structure of the element. In FIG. 12B, all trenches are filled with doped poly or combination of doped poly and non-doped poly to from trench gates 124, trench gate 124′ for gate contact and floating trench gates 125. Then, the filling-in material is etched back or CMP (Chemical Mechanical Polishing ) to expose the potion of the gate oxide layer 130 that extends over the surface of epitaxial layer. For further reducing gate resistance, a layer of silicide is formed on top of poly or inside of the doped poly (not shown) as alternative. An Ion Implantation is then applied to form P-body 144, followed by a P-body diffusion step for P-body region drive-in. Next, an N+ mask is employed to define N+ source region 146, the most important is that, N+ source region is Ion Implanted only and not followed by diffusion as process flow as deep trench contact as before.

In FIG. 12C, the process continues with the deposition of contact oxide layer 150 over entire structure. A contact mask is applied to carry out a contact etch to open the source-body contact trench 134a and gate contact trench 134′a. Said source-body contact trenches are opened by applying a dry oxide etching through contact oxide layer 150, gate oxide 130 and followed by a dry silicon etching into source region 146 and P-body region 144 for body contact; said gate contact trench is opened by applying a dry oxide etching through contact oxide layer 150, and followed by a dry poly etching into trench gate 124′ for gate contact. Then, the N+ source diffusion is performed to make the N+ junction deeper than said source contact trench in silicon. A BF 2 Ion Implantation process (20˜60 KeV; 5E14˜2E15 cm⁻²) is followed for the formation of contact hole 135 underneath source contact trench and body contact trench for reducing the contact resistance between P-body region 144 and contact metal plug. According to some preferred embodiment of the present invention, a Boron Ion Implantation (100˜200 KeV; 1E13˜1E14⁻² cm) is carried out to form P* area 136 underneath P+ for further enhancing avalanche current.

In accordance with the fifth embodiment shown in FIG. 8 and in FIG. 12D, contact trenches are filled with Ti/TiN/W by a Ti/TiN/W deposition. Then, W and Ti/TiN etch back is performed to form trench source-body contact 134, trench gate contact 134′. After that, an interconnection metal layer and front metal layer is deposited onto whole surface and a metal mask is applied to pattern the interconnection metal layer into source interconnection metal 158 and gate interconnection metal 158′, and to pattern the front metal layer into front source metal 160 and front gate metal 160′. The source metal 160 is in electrical contact with the trenched source-body contact plug, while the gate metal 160′ is in electrical with the trenched gate contact.

In accordance with the sixth embodiment shown in FIG. 9 and in FIG. 12E, contact trenches are filled by a Ti/TiN/Al alloys deposition without etching back. A metal mask is then employed to pattern the deposited metal into source metal 160 and gate metal 160′ by a metal etching process.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A vertical semiconductor power MOS device comprising a plurality of semiconductor power cells with each cell comprising a trenched gate surrounded by a source region encompassed in a body region above a drain region disposed on a bottom surface of a substrate, wherein said MOS cell further comprising:
a low-resistivity substrate to reduce Rds;
a plurality of trench gates and at least a wider trench gate for gate contact;
a plurality of floating trench gates as termination rings;
a doped area underneath said trench bottom with the same doping type as epitaxial layer but doping concentration is heavier than epitaxial layer, to further reduce Rds;
a source-body contact trench opened through a contact oxide layer covering said cell structure and extending into said body region with the contact trench depth in epitaxial layer shallower than source junction depth;
a gate contact trench opened through said insulating layer and extending into trench-filling material in said trenched gate underneath gate runner metal;
a source metal and gate metal layer formed on a top surface of the MOSFET; and
a drain metal layer formed on a bottom surface of the MOSFET.

2. The MOSFET of claim 1, the substrate is phosphorus doped with resistivity less than 2.0 mohm-cm.

3. The MOFET of claim 1 has heavily doped layer underneath source-body contact trench with doping type same as said body layer for ohmic contact and avalanche current enhancement. The dose of said heavily doped layer ranges from 5E14 to 4E15. cm−2.

4. The MOFET of claim 1 has a doped layer underneath said the heavily doped layer with doping type same as said body layer for further improving avalanche current. The dose of said doped layer ranges from 1E13 to 1E14 cm−2.

5. The MOSFET of claim 1 wherein said trench-filling material is doped poly.

6. The MOSFET of claim 1 wherein said trench-filling material is combination of doped poly and non-doped poly.

7. The MOSFET of claim 1 wherein said trench-filling material is doped poly with silicide on the poly top.

8. The MOSFET of claim 1 wherein said trench-filling material is doped poly with silicide inside the doped poly.

9. The MOSFET of claim 1 wherein said trench contact is filled with Ti/TiN/W, Co/TiN/W or Mo/Ti/W connected with Al Alloys as source and gate metal.

10. The MOSFET of claim 1 wherein said trench contact is filled with Ti/TiN/Al Alloys, Co/TiN/Al alloys or Mo/TiN/Al alloys as source and gate metal.

11. A method for manufacturing a trench MOSFET with shallow trench contact comprising the steps of:
growing an epitaxial layer upon a heavily N doped substrate, wherein said epitaxial layer is doped with a first type dopant, eg., N dopant;
forming a trench mask with open and closed areas on the surface of said epitaxial layer;
removing semiconductor material from exposed areas of said trench mask to form a plurality of gate trenches;
depositing a sacrificial oxide layer onto the surface of said trenches to remove the plasma damage introduced during opening said trenches;
removing said sacrificial oxide and said trench mask;
implanting whole device with Arsenic ion to form n* area underneath each gate trench;
depositing gate oxide on the surface of said epitaxial layer and along the inner surface of said gate trenches;
depositing a layer of doped poly or combination doped poly and non-doped poly onto said gate oxide and into said gate trenches;
etching back or CMP said doped poly or combination doped poly and non-doped poly from the surface of said gate oxide and leaving enough doped poly or combination doped poly and non-doped poly into said gate trenches to serve as trench gate material;
forming silicide on top poly as alternative for low Rg;
implanting said epitaxial layer with a second type dopant to form P-body regions;
depositing a source mask with open and closed areas to define n+ source regions;
implanting whole device with a first type dopant to form source regions;
removing said source mask and forming a thick contact oxide onto whole surface;
forming a contact mask on the surface of said contact oxide layer and removing oxide material and semiconductor material, as well as poly material from exposed areas of said contact mask to open a plurality of contact trenches;
driving in n+ ion of source region by n+ source diffusion to make n+ junction deeper than the trench source contact in silicon;
implanting BF 2 ion to form P+ area underneath source contact trench and body contact trench;
depositing Ti/TiN/W consequently into contact trenches and on the front surface;
etching back W and Ti/TiN to form contact metal plug and depositing a layer of Ti or TiN and then a layer of Al alloys whereon; and
forming a metal mask onto said Al alloys with open and closed areas and removing metal material from the exposed areas of said metal mask to form interconnection metal and front metal.

12. The method of claim 11, wherein forming said gate trenches comprises etching said epitaxial layer according to the open areas of said trench mask.

13. The method of claim 11, wherein forming said P-body regions comprises a step of diffusion to achieve a certain after P-body implantation step.

14. The method of claim 11, wherein forming said contact trenches comprise etching through said contact oxide and said gate oxide by dry oxide etching according to the exposed areas of said contact mask.

15. The method of claim 11, wherein forming said contact trenches comprise etching into n+ source region and p-body region by dry silicon etching according to the exposed areas of said contact mask.

16. The method of claim 11, wherein forming said contact trenches comprise etching into doped poly or combination of doped poly and non-doped poly by dry poly etching according to the exposed areas of said contact mask.

17. The method of claim 11, wherein forming said contact trenches comprises forming terrace contact trenches.

18. The method of claim 17, wherein forming said terrace contact trenches comprises forming terrace source contact trench and terrace body contact trench.

19. The method of claim 18, wherein forming said terrace source and body contact trenches comprises forming terrace contact with contact width near the surface of contact oxide larger than contact width in source portion.

20. The method of claim 11, wherein forming said P+ area underneath source contact trench and body contact trench comprises forming said P+ area with a concentration of 5E14˜2E15 cm⁻² under 20˜60 KeV.

21. The method of claim 11, after the formation of P+ area underneath source contact trench and body contact trench, a Boron Ion Implantation is followed to form P* region under P+ area for further enhancing avalanche current.

22. The method of claim 21, wherein forming said P* region comprises forming said P* region with a concentration of 1E13˜1E14 cm⁻² under 100˜200 KeV.

23. The method of claim 11, wherein forming said interconnection metal and front metal comprises etching Al Alloys and Ti or TiN by dry metal etching according to the exposed areas of said metal mask.

24. The method of claim 11, wherein forming said contact plug comprises refilling contact trenches with Al Alloys to serve as contact metal and front metal.
